(19) United States
(12) Patent Application Publication
(10) Pub. No.: US 2003/0203517 A1
(43) Pub. Date: Oct. 30, 2003

(54) Method of manufacturing semiconductor device

(76) Inventors: Tadashi Suzuki, Higashimurayama (JP); Tadami Ishida, Hitachinaka (JP); Mikio Shimizu, Higashiibaraki (JP)

Correspondence Address: MATTINGLY, STANGER & MALUR, P.C., Suite 370, 1800 Diagonal Road, Alexandria, VA, 22314, US

(21) Appl. No.: 10/359,237

(22) Filed: Feb. 6, 2003

(30) Foreign Application Priority Data
Apr. 26, 2002 (JP) 2002-125061

(51) Int. Cl. H01L 21/66; H01L 21/425

(52) U.S. Cl. 438/14; 438/308; 438/530

(57) ABSTRACT

Disclosed is a technique capable of preventing the breakage of a semiconductor wafer with a diameter of 300 mm in an RTP equipment. When the RTP process composed of a heating process, a main process for maintaining the predetermined final temperature for a predetermined time, and a cooling process is performed to a semiconductor wafer with a diameter of 300 mm, the temperature of the semiconductor wafer is measured by the use of pyrometers, an open-loop control in which the difference in the in-plane temperature of a semiconductor wafer is controlled within 90° C. is performed in the heating process at a temperature lower than 500° C., and a closed-loop control is performed in the heating process at a temperature of 500° C. or higher and in the main process. In this manner, it is possible to reduce the warp of the semiconductor wafer and to prevent the breakage thereof.

### TECHNICAL FIELD OF THE INVENTION

The present invention relates to a technique for manufacturing a semiconductor device, more particularly, the present invention relates to a technique effectively applied to a thermal treatment process of a semiconductor wafer employing an RTP (Rapid Thermal Processing) system.

### BACKGROUND OF THE INVENTION

With the scaling down of the minimum design rule of a semiconductor device, a shallow junction with a depth of, for example, 0.1 μm or smaller has been required. The shallow junction can be formed by a shallow implantation of impurity ions into a substrate with lower acceleration energy. However, in order to rearrange the ion-implanted impurity at each lattice point and activate the same, alternatively, in order to repair the damages on the crystal caused by the ion implantation, it is necessary to perform a thermal treatment to the substrate.

Therefore, instead of the batch type thermal treatment equipment in which the temperature of a substrate is relatively slowly increased and decreased, the RTP equipment capable of increasing the temperature at the rate of 10° C. per second or higher is used in the thermal treatment process. In this manner, the shallow junction can be formed by the use of the ion implantation and the thermal treatment.

In the case of using the RTP equipment, various techniques are used in the method and the equipment of the thermal treatment so as to achieve the uniformity in the in-plane temperature of the semiconductor wafer.

For example, Japanese Patent Application Laid-Open No. 6-260426 discloses a method and equipment as follows. That is, temperature measurement positions measured by pyrometers are set at a plurality of different positions, for example, at the positions in the peripheral part of a wafer and apart from the center of the wafer by the length equivalent to 70% of the wafer radius, and the semiconductor wafer is heated while controlling the temperature difference among the plurality of the measurement positions within 5° C. in both the heating process and in the period for maintaining the high temperature.

Further, the U.S. Pat. No. 5,920,797 discloses a method of reducing stress when heating a semiconductor wafer having a diameter of 300 mm by controlling the temperature difference between the center portion and peripheral portion of the wafer.

Also, in the RTP equipment using the lamp heating, a so-called closed-loop control is employed in which the temperature of a semiconductor wafer is monitored by the use of pyrometers and the measurement results are fed back to the lamp power, thereby controlling the temperature of the semiconductor wafer.

### SUMMARY OF THE INVENTION

The inventors of this invention have examined the method of performing the thermal treatment to a semiconductor wafer with a diameter of 300 mm by the use of the RTP equipment provided with halogen lamps as heat sources.

In a temperature range where the temperature of the semiconductor wafer is lower than 500° C., the light absorption of single crystal silicon which constitutes a semiconductor wafer is relatively weakened at the wavelength range of about 1 to 5 μm. Therefore, the pyrometers having the detection wavelength of about 0.8 to 2.5 μm inevitably detect the ambient light, for example, the halogen lamp light with a wavelength in an infrared range with its peak of about 1 μm. As a result, the problem is caused, that is, the temperature of the semiconductor wafer cannot be measured with accuracy.

For its solution, in the heating process in which the temperature of the semiconductor wafer is lower than 500° C., a so-called open-loop control is employed in which the lamp power to heat the semiconductor wafer is determined in advance. Thereafter, when the temperature of the semiconductor wafer reaches about 500° C., the open-loop control is switched to the closed-loop control, and then, the heating higher than 500° C. and the main process for maintaining the predetermined final temperature for a predetermined time are performed.

However, since the uniformity of the in-plane temperature of the semiconductor wafer is maintained by rotating the semiconductor wafer during the RTP process, in the case where the warp is caused in the semiconductor wafer, the semiconductor wafer falls off from the stage of the equipment during the RTP process and the semiconductor wafer is broken in some cases.

In the case of using a semiconductor wafer with a diameter of 300 mm, the in-plane temperature of the wafer becomes nonuniform during its heating, and the absolute value of the amount of the warp of the semiconductor wafer is larger than that of the semiconductor wafer with a diameter of 200 mm or smaller. Also, in the heating process at a temperature lower than 500° C. using the open-loop control, the in-plane temperature of the semiconductor wafer is apt to be nonuniform in comparison to that in the heating process at the temperature of 500° C. or higher, the main process, and the cooling process using the closed-loop control.

As described above, when performing the RTP process to the semiconductor wafer with a diameter of 300 mm, the problem of the breakage of the semiconductor wafer due to the warp of the semiconductor wafer becomes noticeable particularly in the heating process at the temperature lower than 500° C. using the open-loop control.

An object of the present invention is to provide a technique capable of preventing the breakage of a semiconductor wafer with a diameter of 300 mm in an RTP equipment.

The above and other objects and novel characteristics of the present invention will be apparent from the description and the accompanying drawings of this specification.

The typical ones of the inventions disclosed in this application will be briefly described as follows.

In the present invention, when an RTP process including a heating process, a main process for maintaining the predetermined final temperature for a predetermined time, and a cooling process is performed by a single wafer processing manner to a semiconductor wafer with a diameter of 300 mm, the temperature of the semiconductor wafer is measured by the use of pyrometers, an open-loop control in which the difference in the in-plane temperature of the semiconductor wafer is controlled within 90° C. is performed in the heating process at a temperature lower than 500° C., and a closed-loop control is performed in the heating process at a temperature of 500° C. or higher and in the main process.

In the present invention, when an RTP process including a heating process, a main process for maintaining the predetermined final temperature for a predetermined time, and a cooling process is performed by a single wafer processing manner to a semiconductor wafer with a diameter of 300 mm, the temperature of the semiconductor wafer in the heating process at a temperature lower than 500° C. is measured by the use of first pyrometers with a first detection wavelength, and the temperature of the semiconductor wafer in the heating process at a temperature of 500° C. or higher is measured by the use of second pyrometers with a second detection wavelength which is different from the first detection wavelength, and the closed-loop control is employed in both of the heating processes of the respective temperature ranges.

### BRIEF DESCRIPTIONS OF THE DRAWINGS

FIG. 1 is a schematic diagram showing a semiconductor wafer and an arrangement of pyrometers provided in an RTP equipment for explaining an embodiment of the present invention;

FIG. 2 is a graph representing an example of a temperature distribution in a semiconductor wafer with a diameter of 300 mm during an RTP process measured by the use of the five pyrometers shown in FIG. 1;

FIG. 3 is a graph representing an example of the difference in the in-plane temperature of the semiconductor wafer with a diameter of 300 mm during a heating process at a temperature lower than 500° C. using an open-loop control;

FIG. 4 is a sectional view of the principal part of a semiconductor substrate for illustrating an example where the present invention is applied to the method of manufacturing a CMOS device along the order of the process;

FIG. 5 is a sectional view of the principal part of a semiconductor substrate for illustrating an example where the present invention is applied to the method of manufacturing a CMOS device along the order of the process;

FIG. 6 is a sectional view of the principal part of a semiconductor substrate for illustrating an example where the present invention is applied to the method of manufacturing a CMOS device along the order of the process;

FIG. 7 is a sectional view of the principal part of a semiconductor substrate for illustrating an example where the present invention is applied to the method of manufacturing a CMOS device along the order of the process;

FIG. 8 is a sectional view of the principal part of a semiconductor substrate for illustrating an example where the present invention is applied to the method of manufacturing a CMOS device along the order of the process; and

FIG. 9 is a sectional view schematically showing a semiconductor wafer and an RTP equipment for explaining another embodiment of the present invention.

### DESCRIPTION OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof is omitted.

(First Embodiment)

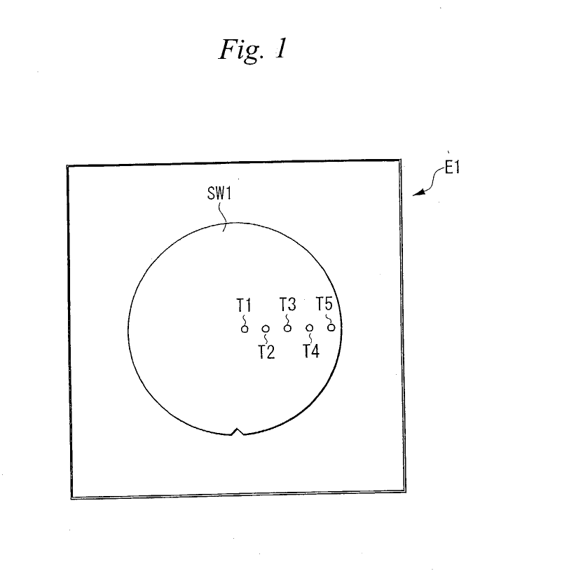

FIG. 1 is a schematic diagram showing a semiconductor wafer and an arrangement of pyrometers provided in an RTP equipment for explaining an embodiment of the present invention. Note that, though not shown, halogen lamps with a wavelength in an infrared range with its peak of about 1 μm are taken as an example of a heat source of the RTP equipment.

In an RTP equipment E1, five pyrometers T1 to T5 are provided along a radius of a semiconductor wafer SW1 at almost regular intervals, and the detection wavelength thereof is, for example, about 0.8 to 2.5 μm. In addition, the temperature in each of the regions obtained by dividing the semiconductor wafer SW1 into five regions in accordance with the positions of the pyrometers T1 to T5 can be independently controlled by the halogen lamps. A diameter of the semiconductor wafer SW1 is 300 mm, and the semiconductor wafer SW1 is rotated during the RTP process so as to improve the uniformity in the in-plane temperature of the semiconductor wafer SW1.

In FIG. 1, the RTP equipment E1 having the pyrometers T1 to T5 is exemplified. However, the number of the pyrometers is not limited to five, and a number of pyrometers necessary to control the difference in the in-plane temperature of the semiconductor wafer SW1 within a predetermined range are provided in the RTP equipment E1. Also, the arrangement of the pyrometers is not limited to that as shown in FIG. 1 in which they are arranged at regular intervals.

Note that the difference in the in-plane temperature of the semiconductor wafer SW1 indicates the maximum difference among the temperatures measured by the pyrometers T1 to T5, and the temperature difference can be adjusted by changing the setting conditions of the lamp power of the halogen lamps.

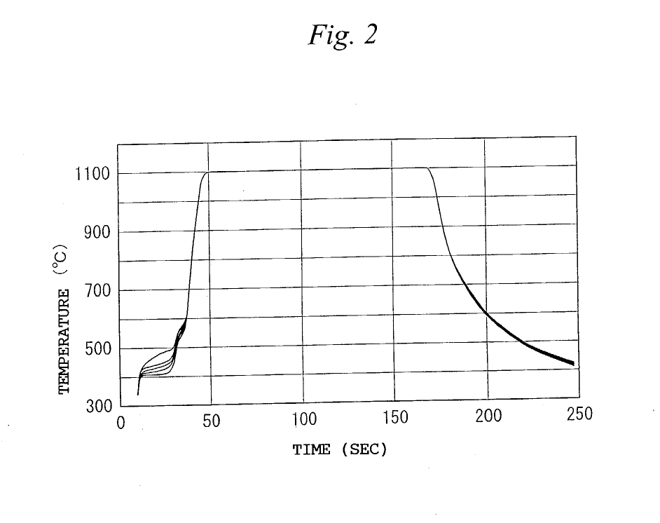

FIG. 2 is a graph representing an example of the temperature distribution in the semiconductor wafer with a diameter of 300 mm during the RTP process measured by the five pyrometers shown in FIG. 1.

In the heating process in which the temperature of the semiconductor wafer SW1 is 500° C. or higher and in the main process in which the temperature of the same is 1100° C., the temperature of the semiconductor wafer SW1 is measured by the use of the five pyrometers T1 to T5, and the measurement results are fed back to the lamp power of the halogen lamps, thereby controlling the temperature of the semiconductor wafer SW1 (closed-loop control). In this manner, it is possible to obtain the almost uniform in-plane temperature in the semiconductor wafer SW1.

Contrary to this, in the heating process in which the temperature of the semiconductor wafer SW1 is lower than 500° C., since the pyrometers T1 to T5 detect the ambient light, for example, halogen lamp light, the temperature of the semiconductor wafer SW1 cannot be accurately monitored. Therefore, the lamp power of the halogen lamps is set in advance and the semiconductor wafer SW1 is heated in line with the set lamp power (open-loop control). For these reasons, the difference in the in-plane temperature frequently occurs in the semiconductor wafer SW1.

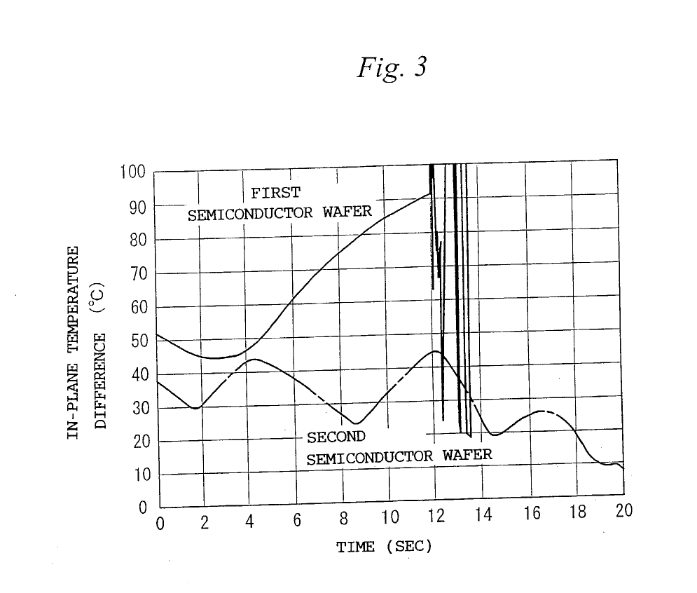

FIG. 3 is a graph representing an example of the difference in the in-plane temperature of the semiconductor wafer with a diameter of 300 mm during the heating process at a temperature lower than 500° C. using the open-loop control. In FIG. 3, the solid line represents the difference in the in-plane temperature of the first semiconductor wafer and the chain line represents the difference in the in-plane temperature of the second semiconductor wafer. The five pyrometers shown in FIG. 1 are used in the temperature measurement of the first and second semiconductor wafers. The lamp power of the halogen lamps are set so that the temperature of the first and second semiconductor wafers can reach about 500° C. in about 20 seconds. However, the setting conditions of the halogen lamps are different from each other in the first and second semiconductor wafers.

In the second semiconductor wafer in which the difference in the in-plane temperature is controlled within 50° C., the temperature thereof reaches 500° C. in 20 seconds without breakage. Thereafter, the second semiconductor wafer is heated after the open-loop control is switched to the closed-loop control, and then, the main process at 1100° C. is performed.

Meanwhile, the first semiconductor wafer is fallen off from the stage of the RTP equipment and broken at the time when the difference in the in-plane temperature reaches about 90° C. (in about 12 seconds). The subsequent extreme ups and downs in the difference in the in-plane temperature are caused because the pyrometers directly measure the light from the halogen lamps.

Therefore, when the difference in the in-plane temperature of the semiconductor wafer reaches 90° C. or higher in the heating process at a temperature lower than 500° C. using the open-loop control, it is considered that the semiconductor wafer is frequently fallen off from the stage of the RTP equipment due to the warp of the semiconductor wafer. Accordingly, in order to prevent the breakage of the semiconductor wafer with a diameter of 300 mm, it is necessary to control the difference in the in-plane temperature of the semiconductor wafer within 90° C. in the heating process at a temperature lower than 500° C. using the open-loop control.

As a method of controlling the difference in the in-plane temperature of the semiconductor wafer within 90° C. in the heating process at a temperature lower than 500° C. using the open-loop control, the three methods described below can be exemplified.

The first method is as follows. That is, the relationship between the semiconductor wafer and the lamp power of a plurality of halogen lamps in a temperature range of 200 to 500° C. is obtained in advance with using a thermometer other than the pyrometer such as a thermoelectric couple. Then, the lamp power conditions of each halogen lamp are appropriately set, thereby controlling the difference in the in-plane temperature of the semiconductor wafer within 90° C. For example, a semiconductor wafer having a thermoelectric couple implanted therein can be used as a semiconductor wafer to measure the temperature. In this method, it is possible to achieve a relatively high heating rate of the semiconductor wafer, for example, 10° C. per second or higher in both temperature ranges such as lower than 500° C. and 500° C. or higher.

The second method is as follows. That is, the heating rate of the semiconductor wafer inserted in the chamber of the RTP equipment in the temperature range of lower than 500° C. is set relatively low, for example, lower than 10° C. per second by gradually increasing the lamp power of the plurality of halogen lamps. By so doing, the difference in the in-plane temperature of the semiconductor wafer is controlled within 90° C. In this method, it is possible to set the lamp power conditions of all of the halogen lamps equal to each other. In addition, it is also possible to set a relatively high heating rate of the semiconductor wafer in the temperature range of 500° C. or higher, for example, 10° C. per second or higher.

The third method is as follows. That is, the temperature of the semiconductor wafer is obtained by subtracting the amount of temperature rise caused by the halogen lamp light from the value measured by the pyrometers. By so doing, the difference in the in-plane temperature of the semiconductor wafer is controlled within 90° C. The wafer temperature dependency can be taken as the temperature rise caused by the halogen lamp light in the value measured by the pyrometers, and the characteristics thereof are obtained in advance and the obtained characteristics are installed in the temperature control system. According to the method, it is possible to obtain the difference in the in-plane temperature of the wafer even in the temperature range lower than 500° C.

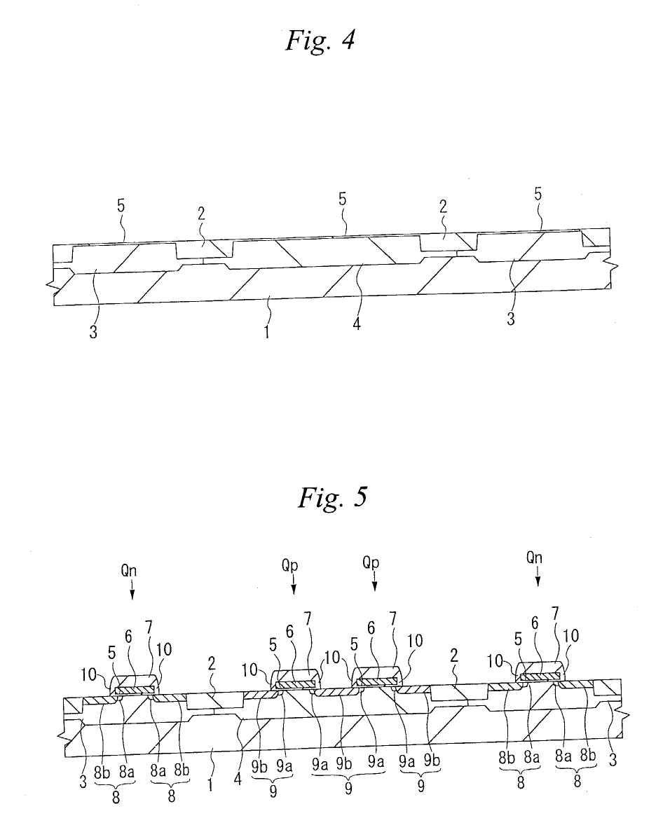

Next, an example in which the present invention is applied to the method of manufacturing a CMOS (Complementary Metal Oxide Semiconductor) device will be described with using the sectional views of the principal part of the semiconductor substrate shown in FIGS. 4 to 8.

First, as shown in FIG. 4, a semiconductor substrate 1 made of, for example, p type single crystal silicon is prepared. The semiconductor substrate 1 is a semiconductor wafer processed into the shape of a thin circular plate with a diameter of 300 mm. Next, device isolation trenches are formed on the semiconductor substrate 1 in the device isolation region. Thereafter, a silicon oxide film deposited over the semiconductor substrate 1 by the CVD (Chemical Vapor Deposition) method is polished by the etchback or the CMP (Chemical Mechanical Polishing) method, thereby leaving the silicon oxide film in the device isolation trenches. In this manner, device isolations 2 are formed.

Next, an impurity is ion-implanted into the semiconductor substrate 1 with using a resist pattern as a mask, thereby forming a p well 3 and an n well 4. An impurity having p-type conductivity such as boron is ion-implanted into the p well 3, and an impurity having n-type conductivity such as phosphorus is ion-implanted into the n well 4. Thereafter, an impurity for controlling the threshold value of the MISFET (Metal Insulator Semiconductor Field Effect Transistor) can be ion-implanted into each of the well regions.

Next, a silicon oxide film to be a gate insulating film 5 with a thickness of about 2 nm is formed over the surface of the semiconductor substrate 1 with using a single wafer type RTP equipment provided with halogen lamps as heat sources.

First, the semiconductor substrate 1 is inserted in the chamber of the single wafer type RTP equipment, and then, the temperature of the semiconductor substrate 1 is increased to substrate 1 is controlled within 90° C. Thereafter, at the time about 500° C. by using the open-loop control in which the difference in the in-plane temperature of the semiconductor when the temperature of the semiconductor substrate 1 reaches about 500° C., the open-loop control is switched to the closed-loop control and the semiconductor substrate 1 is further heated to 900° C. Subsequently, after the thermal oxidation process for a predetermined time at 900° C. is performed to the semiconductor substrate 1, the power of the halogen lamps is turned off to cool the semiconductor substrate 1. Then, the semiconductor substrate 1 is taken out from the chamber of the single wafer type RTP equipment at the time when the temperature of the semiconductor substrate 1 is reduced to, for example, about 150 to 200° C.

Next, as shown in FIG. 5, a polycrystalline silicon film to be a gate electrode and a silicon oxide film to be a cap insulating film are sequentially deposited to form a laminated film. Thereafter, the laminated film is etched with using a resist pattern as a mask, thereby forming a gate electrode 6 and a cap insulating film 7.

Subsequently, an impurity with the n-type conductivity such as arsenic is ion-implanted into the p well 3, thereby forming n type extended regions 8a on both sides of the gate electrode 6 on the p well 3. The n type extended region 8a is formed in the self-alignment manner with the gate electrode 6. Similarly, an impurity with the p-type conductivity such as boron fluoride is ion-implanted into the n well 4, thereby forming p type extended regions 9a on both sides of the gate electrode 6 on the n well 4. The p type extended region 9a is formed in the self-alignment manner with the gate electrode 6.

Thereafter, a silicon oxide film is deposited over the semiconductor substrate 1 by the CVD method, and then, the anisotropic etching is performed to the silicon oxide film, thereby forming a sidewall spacer 10 on the sidewall of the gate electrode 6.

Next, an impurity with the n-type conductivity such as arsenic is ion-implanted into the p well 3, thereby forming n type diffusion regions 8b on both sides of the gate electrode 6 on the p well 3. The n type diffusion region 8b is formed in the self-alignment manner with the gate electrode 6 and the sidewall spacer 10, and the n type semiconductor regions 8 comprised of the n type extended region 8a and the n type diffusion region 8b function as the source and the drain of the n channel MISFET Qn.

Similarly, an impurity with the p-type conductivity such as boron fluoride is ion-implanted into the n well 4, thereby forming p type diffusion regions 9b on both sides of the gate electrode 6 on the n well 4. The p type diffusion region 9b is formed in the self-alignment manner with the gate electrode 6 and the sidewall spacer 10, and the p type semiconductor regions 9 comprised of the p type extended region 9a and the p type diffusion region 9b function as the source and the drain of the p channel MISFET Qp.

Subsequently, a thermal treatment for activating the impurity ion-implanted into the semiconductor substrate 1 is performed to the semiconductor substrate 1 with using the single wafer type RTP equipment.

First, the semiconductor substrate 1 is inserted in the chamber of the single wafer type RTP equipment, and then, the temperature of the semiconductor substrate 1 is increased to about 500° C. by using the open-loop control in which the difference in the in-plane temperature of the semiconductor substrate 1 is controlled within 90° C. Thereafter, at the time when the temperature of the semiconductor substrate 1 reaches about 500° C., the open-loop control is switched to the closed-loop control and the semiconductor substrate 1 is further heated to 1000° C. Subsequently, after the main process for a predetermined time at 1000° C. is performed to the semiconductor substrate 1, the power of the halogen lamps is turned off to cool the semiconductor substrate 1. Then, the semiconductor substrate 1 is taken out from the chamber of the single wafer type RTP equipment at the time when the temperature of the semiconductor substrate 1 is reduced to, for example, about 150 to 200° C.

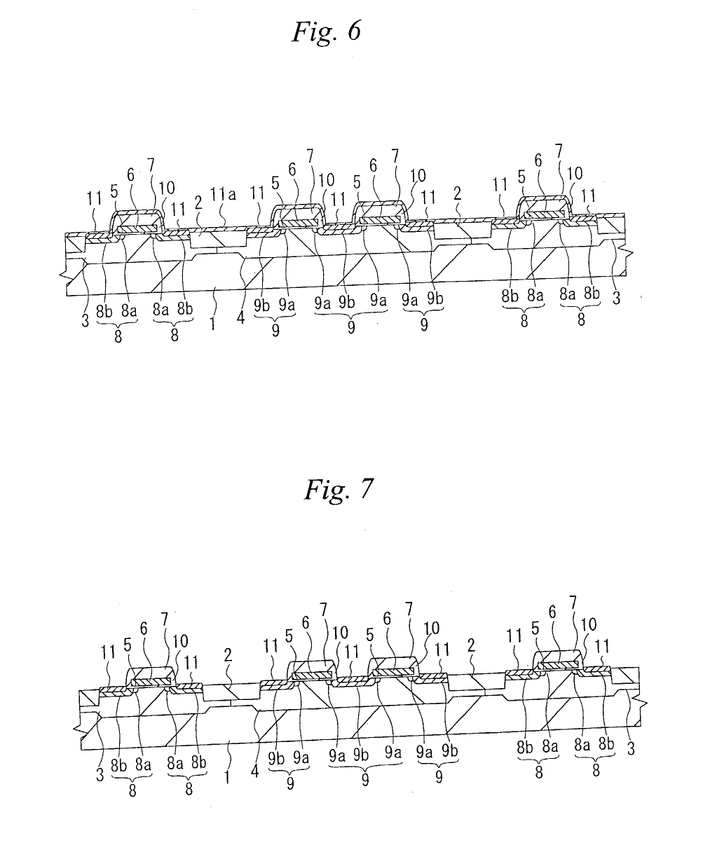

Next, as shown in FIG. 6, a cobalt film 11a with a thickness of about 10 to 20 nm is deposited on the semiconductor substrate 1 by, for example, the sputtering method. Subsequently, a thermal treatment is performed to the semiconductor substrate 1 by the use of the single wafer type RTP equipment. By so doing, a silicide layer 11 with a thickness of about 30 nm is selectively formed on the surface of the n type semiconductor regions 8 to be the source and the drain of the n channel MISFET Qn and on the surface of the p type semiconductor regions 9 to be the source and the drain of the p channel MISFET Qp.

First, the semiconductor substrate 1 is inserted in the chamber of the single wafer type RTP equipment, and then, the temperature of the semiconductor substrate 1 is increased to near 500° C. by using the open-loop control in which the difference in the in-plane temperature of the semiconductor substrate 1 is controlled within 90° C. Thereafter, the open-loop control is switched to the closed-loop control to maintain the temperature of the semiconductor substrate 1 at 500° C. and the main process at 500° C. is performed to the semiconductor substrate 1 for a predetermined time. Thereafter, the power of the halogen lamps is turned off to cool the semiconductor substrate 1. Subsequently, the semiconductor substrate 1 is taken out from the chamber of the single wafer type RTP equipment at the time when the temperature of the semiconductor substrate 1 is reduced to, for example, about 150 to 200° C.

Next, as shown in FIG. 7, the unreacted cobalt film 11a is removed, and then, the thermal treatment for reducing the resistance of the silicide layer 11 is performed to the semiconductor substrate 1 by the use of the single wafer type RTP equipment.

First, the semiconductor substrate 1 is inserted in the chamber of the single wafer type RTP equipment, and then, the temperature of the semiconductor substrate 1 is increased to about 500° C. by using the open-loop control in which the difference in the in-plane temperature of the semiconductor substrate 1 is controlled within 90° C. Thereafter, at the time when the temperature of the semiconductor substrate 1 reaches about 500° C., the open-loop control is switched to the closed-loop control and the semiconductor substrate 1 is further heated to 800° C. Subsequently, after the main process for a predetermined time at 800° C. is performed to the semiconductor substrate 1, the power of the halogen lamps is turned off to cool the semiconductor substrate 1. Subsequently, the semiconductor substrate 1 is taken out from the chamber of the single wafer type RTP equipment at the time when the temperature of the semiconductor substrate 1 is reduced to, for example, about 150 to 200° C.

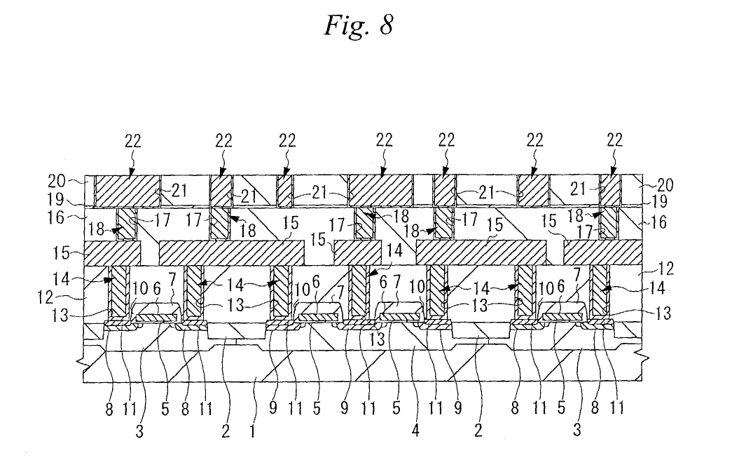

Next, as shown in FIG. 8, after forming a silicon oxide film 12 over the semiconductor substrate 1, the silicon oxide film 12 is polished by, for example, the CMP method, thereby planarizing the surface of the silicon oxide film. Subsequently, contact holes 13 are formed in the silicon oxide film 12 by the etching using a resist pattern as a mask. These contact holes 13 are formed on required portions such as on the n type semiconductor region 8 and on the p type semiconductor region 9.

Subsequently, a titanium nitride film is formed by, for example, the CVD method over the entire surface of the semiconductor substrate 1 and in the contact holes 13, and a tungsten film for filling the contact holes 13 is formed by, for example, the CVD method. Thereafter, the titanium nitride film and the tungsten film outside the contact holes 13 are removed by the CNP method, thereby forming plugs 14 having a main conductive layer composed of the tungsten film in the contact holes 13.

Next, after forming a tungsten film over the semiconductor substrate 1, the tungsten film is processed by the etching using a resist pattern as a mask, thereby forming first layer wirings 15. The CVD method or the sputtering method is available to form the tungsten film.

Next, after forming an insulating film, for example, a silicon oxide film for covering the wiring 15, the insulating film is polished by the CMP method, thereby forming an interlayer insulating film 16 having a planarized surface. Subsequently, contact holes 17 are formed in predetermined portions of the interlayer insulating film 16 by the etching using a resist pattern as a mask.

Subsequently, a barrier metal layer is formed over the entire surface of the semiconductor substrate 1 and in the contact holes 17, and then, a copper film for filling the contact holes 17 is formed. A titanium nitride film, a tantalum film, or a tantalum nitride film is used as the barrier metal layer, and the barrier metal layer is formed by, for example, the CVD method or the sputtering method. The copper film functions as a main conductive layer and is formed by, for example, the plating method. It is possible to form a thin copper film as a seed layer by, for example, the CVD method or the sputtering method before forming the copper film by the plating method. Thereafter, the copper film and the barrier metal layer outside the contact holes 17 are removed by the CMP method, thereby forming plugs 18 in the contact holes 17.

Next, a stopper insulating film 19 is formed over the semiconductor substrate 1, and then, an insulating film 20 for forming wirings is formed thereon. For example, a silicon nitride film is used as the stopper insulating film 19 and a silicon oxide film is used as the insulating film 20. Then, wiring trenches 21 are formed in the predetermined portions of the stopper insulating film 19 and the insulating film 20 by the etching using a resist pattern as a mask.

Subsequently, a barrier metal layer is formed over the entire surface of the semiconductor substrate 1 and in the wiring trenches 21, and then, a copper film used to fill the wiring trenches 21 is formed. Thereafter, the copper film and the barrier metal layer outside the wiring trenches 21 are removed by the CMP method. By so doing, second wiring layers 22 having the copper film as a main conductive layer are formed in the wiring trenches 21. Thereafter, wirings are formed further thereon, and thus, the CMOS device is almost completed. However, illustrations and descriptions thereof are omitted.

Note that the case where a semiconductor wafer is apt to be broken due to the warp of the semiconductor wafer when the difference in the in-plane temperature of the semiconductor wafer reaches 90° C. or higher in the heating process at a temperature lower than 500° C. using the open-loop control has been described in the first embodiment. However, it can be considered that a semiconductor wafer is apt to be broken due to the warp of the semiconductor wafer when the difference in the in-plane temperature of the semiconductor wafer reaches 90° C. or higher even in the heating process at 500° C. or higher, in the main process, and in the cooling process using the closed-loop control. Therefore, it is necessary to control the difference in the in-plane temperature of the semiconductor wafer within 90° C. even in the heating process at 500° C. or higher, in the main process, and in the cooling process using the closed-loop control.

Also, in the first embodiment, the five pyrometers T1 to T5 are arranged at almost regular intervals. However, it is also possible to arrange the pyrometers at various intervals.

Also, the case where the present invention is applied to the method of manufacturing a CMOS device has been described in the first embodiment. However, it is also possible to apply the present invention to the method of manufacturing any kind of semiconductor devices, and it is possible to achieve the same advantages.

As described above, according to the first embodiment, in the case where a thermal treatment is performed to a semiconductor substrate with a diameter of 300 mm by the use of the RTP equipment provided with pyrometers, the open-loop control in which the difference in the in-plane temperature of the semiconductor wafer is controlled within 90° C. is used in the heating process in which the temperature of the semiconductor wafer is lower than 500° C., and the closed-loop control is used in the heating process of the semiconductor wafer at 500° C. or higher and in the main process. By so doing, it is possible to reduce the warp of the semiconductor wafer. Therefore, it is possible to prevent the semiconductor wafer from falling off from the stage of the RTP equipment. As a result, it is possible to prevent the breakage of the semiconductor wafer.

(Second Embodiment)

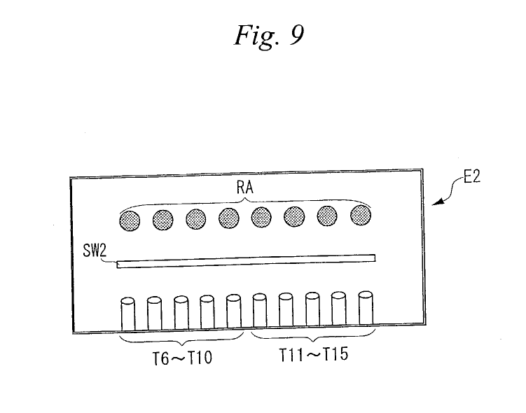

FIG. 9 is a sectional view schematically showing a semiconductor wafer and an RTP equipment for explaining another embodiment of the present invention.

An RTP equipment E2 is provided with halogen lamps RA as a heating system, and the RTP equipment has a function to rotate a semiconductor wafer SW2 during the RTP process. This RTP equipment E2 can perform the heating process to the semiconductor wafer SW2 with a diameter of 300 mm.

In addition, the RTP equipment E2 is provided with two kinds of pyrometers each having different detection wavelengths (the first group of the pyrometers T6 to T10 and the second group of the pyrometers T11 to T15). The temperature control of the semiconductor wafer at a temperature lower than 500° C. can be performed by the closed-loop control using the first group of the pyrometers T6 to T10, and the temperature control of the semiconductor wafer at a temperature of 500° C. or higher can be performed by the closed-loop control using the second group of the pyrometers T11 to T15.

More specifically, the detection wavelength of the first group of the pyrometers T6 to T10 is, for example, the wavelength obtained by removing the wavelength range of about 1 to 5 μm, and the pyrometers T6 to T10 can measure the temperature of the semiconductor wafer SW2 in a range from 200 to 500° C. without the influences of ambient light such as the light from the halogen lamps RA. Also, the detection wavelength of the second group of the pyrometers T10 to T15 is, for example, about 0.8 to 2.5 μm, and the pyrometers T11 to T15 can measure the temperature of 500° C. or higher.

Therefore, in the heating process in which the temperature of the semiconductor wafer SW2 is lower than 500° C., the temperature of the semiconductor wafer SW2 is measured by the use of the first group of the pyrometers T6 to T10, and in the heating process in which the temperature of the semiconductor wafer SW2 is 500° C. or higher and in the main process, the temperature of the semiconductor wafer SW2 is measured by the use of the second group of the pyrometers T11 to T15. Then, each of the results is fed back to the lamp power of the halogen lamps. By so doing, the temperature control of the semiconductor wafer SW2 is performed. As a result, the uniform in-plane temperature can be realized in the semiconductor wafer SW2. Therefore, it is possible to prevent the warp of the semiconductor wafer SW2 and the breakage of the semiconductor wafer SW2.

FIG. 9 illustrates the RTP equipment E2 provided with the first group of the pyrometers T6 to T10 and the second group of the pyrometers T11 to T15. However, the number of each group of the pyrometers is not limited to five, and a number of the first group of the pyrometers and the second group of the pyrometers necessary to control the difference in the in-plane temperature of the semiconductor wafer SW2 within a predetermined range are provided in the RTP equipment E2.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the foregoing embodiments, the RTP equipment employing the lamp heating system using halogen lamps has been described. However, it is also possible to apply the present invention to the RTP equipment employing other heating systems such as a laser heating system, an electron beam heating system, and an ion beam heating system, and it is possible to achieve the same advantages.

The advantages achieved by the typical ones of the inventions disclosed in this application will be briefly described as follows.

The temperature of a semiconductor wafer is measured by the use of pyrometers, the open-loop control in which the difference in the in-plane temperature of the semiconductor wafer is controlled within 90° C. is performed in the heating process in which the temperature of the semiconductor wafer is lower than 500° C., and the closed-loop control is performed in the heating process in which the temperature of the semiconductor wafer is 500° C. or higher and in the main process. Alternatively, the pyrometers having different detection wavelengths are separately used to measure the temperature of the semiconductor wafer in the temperature range in which the temperature of the semiconductor wafer is lower than 500° C. and in the temperature range in which the temperature of the semiconductor wafer is 500° C. or higher, and the closed-loop control is used in each temperature range. In this manner, since the warp of the semiconductor wafer is reduced even when the RTP process is performed to the semiconductor wafer with a diameter of 300 mm, it is possible to prevent the semiconductor wafer from falling off from the stage of the RTP equipment and to prevent the breakage of the semiconductor wafer.

What is claimed is:

1. A method of manufacturing a semiconductor device, in which a thermal treatment comprising a heating process, a main process for maintaining a predetermined final temperature for a predetermined time, and a cooling process is performed by a single wafer processing manner to a semiconductor wafer with a diameter of 300 mm,
wherein difference in an in-plane temperature of the semiconductor wafer is controlled within 90° C. in the thermal treatment.

2. The method of manufacturing a semiconductor device according to claim 1,
wherein a heating rate in the heating process is 10° C. or higher per second.

3. A method of manufacturing a semiconductor device, in which a thermal treatment comprising a heating process, a main process for maintaining a predetermined final temperature for a predetermined time, and a cooling process is performed by a single wafer processing manner to a semiconductor wafer with a diameter of 300 mm,
wherein a temperature of the semiconductor wafer is measured by pyrometers, and difference in an in-plane temperature of the semiconductor wafer is controlled within 90° C. in the heating process in which the temperature of the semiconductor wafer is lower than 500° C.

4. The method of manufacturing a semiconductor device according to claim 3,
wherein an open-loop control is performed in the heating process in which the temperature of the semiconductor wafer is lower than 500° C.

5. The method of manufacturing a semiconductor device according to claim 4,
wherein a closed-loop control is performed in the heating process in which the temperature of the semiconductor wafer is 500° C. or higher and performed in the main process.

6. The method of manufacturing a semiconductor device according to claim 4,
wherein setting conditions of the open-loop control in the heating process in which the temperature of the semiconductor wafer is lower than 500° C. is obtained in advance by the use of thermometers different from the pyrometers.

7. The method of manufacturing a semiconductor device according to claim 6,
wherein a heating rate in the heating process is 10° C. or higher per second.

8. The method of manufacturing a semiconductor device according to claim 4,
wherein the heating rate in the heating process of the semiconductor wafer at a temperature lower than 500° C. is lower than the heating rate in the heating process of the semiconductor wafer at a temperature of 500° C. or higher.

9. The method of manufacturing a semiconductor device according to claim 8,
wherein a heating rate in the heating process in which the temperature of the semiconductor wafer is lower than 500° C. is lower than 10° C. per second; and a heating rate in the heating process in which the temperature of the semiconductor wafer is 500° C. or higher is 10° C. or higher per second.

10. A method of manufacturing a semiconductor device, in which a thermal treatment comprising a heating process, a main process for maintaining a predetermined final temperature for a predetermined time, and a cooling process is performed by a single wafer processing manner to a semiconductor wafer with a diameter of 300 mm,
wherein a temperature of the semiconductor wafer in the heating process in which the temperature of the semiconductor wafer is lower than 500° C. is measured by the use of first pyrometers with a first detection wavelength, and a temperature of the semiconductor wafer in the heating process in which the temperature of the semiconductor wafer is 500° C. or higher is measured by the use of second pyrometers with a second detection wavelength different from the first detection wavelength.

11. The method of manufacturing a semiconductor device according to claim 10,
wherein a heating rate in the heating process is 10° C. or higher per second.

12. The method of manufacturing a semiconductor device according to claim 10,
wherein a closed-loop control is performed in both the heating process in which the temperature of the semiconductor wafer is lower than 500° C. and the heating process in which the temperature of the semiconductor wafer is 500° C. or higher.
